(19) United States
(12) Patent Application Publication
(10) Pub. No.: US 2007/0145538 A1
(43) Pub. Date: Jun. 28, 2007

(54) CMP APPARATUS FOR POLISHING DIELECTRIC LAYER AND METHOD OF CONTROLLING DIELECTRIC LAYER THICKNESS

(76) Inventor: Tsang-Jung Lin, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/306,419

(22) Filed: Dec. 28, 2005

(51) Int. Cl. H01L 23/58

(52) U.S. Cl. 257/629

(57) ABSTRACT

A CMP apparatus has a CMP unit for polishing a dielectric layer, a thickness monitoring unit for monitoring a thickness index of the polished dielectric layer, and a thickness correcting unit for further reducing the thickness of the polished dielectric layer in accordance with the thickness index by etching. The CMP unit, the thickness monitoring unit, and the thickness correcting unit are in-situ installed.

### BACKGROUND OF THE INVENTION

1. Field of the Invention

The present invention pertains to a CMP apparatus for polishing a dielectric layer and a method of controlling a dielectric layer thickness, and more particularly, to a CMP apparatus and a method that in-situ monitors the thickness of a dielectric layer after polished, and in-situ corrects the thickness of the dielectric layer by chemical wet etching.

2. Description of the Prior Art

Chemical mechanical polishing (CMP) technique is one of the most important general planarization skills in VLSI fabrications, and therefore is broadly applied in semiconductor process such as metal interconnection process.

CMP is able to equally remove a target thin film with a rough (topographical) surface disposed on a wafer, so that the wafer can have a regular and planar surface. This planar surface ensures depth of focus (DOF) in successive photolithography process. In order to control the thickness of the target thin film being removed, the end point of CMP process must be accurately detected and quickly decided so as to stop the CMP process in time.

To avoid over-polishing, the thickness control of the target thin film in the CMP process relies on a stop layer disposed underneath the target thin film. The polishing rate of the stop layer is normally smaller than that of the target thin film, so that the CMP process can stop on the stop layer sharply. In some cases, however, the target thin film does not have a stop layer disposed thereunder, and thus the CMP cannot be stopped promptly. In such a case, over-polishing tends to occur, and a re-deposition process must be performed to deposit a same thin film on the target thin film for meeting the thickness requirement.

With reference to FIG. 1, FIG. 1 is a flow chart illustrating a conventional method of controlling a target thin film thickness in a CMP process. As shown in FIG. 1, the conventional method includes the steps as follows:

Step 10: start;

Step 12: load in a wafer to a CMP apparatus;

Step 14: perform a CMP process to a target thin film disposed on the wafer;

Step 16: load out the wafer;

Step 18: detect the thickness of the target thin film after polished, if the thickness of the target thin film equals a predetermined thickness, perform step 22, if the thickness is greater than the predetermined thickness, perform step 12, if the thickness is less than the predetermined thickness, perform step 20;

Step 20: perform a deposition process, and perform step 18; and

Step 22: end.

Referring to FIG. 2, FIG. 2 is a diagram schematically illustrating a feedback control mechanism of a conventional method of controlling the target thin film thickness. As shown in FIG. 2, wafers 1, 2, 3 (numerals 1, 2, 3 denote the sequence of wafers) are subsequently loaded in a CMP apparatus 30 and undergone a CMP process. The wafer 1 is loaded out from the CMP apparatus 30 after polished and delivered to a thickness measure device 32 to detect the difference between the exact thickness and the predetermined thickness of the target thin film. This data is then transferred to the CMP apparatus 30 as a reference to modify process parameters so as to correct the thickness of the target thin films disposed on the wafers 2, 3. If the thickness of the target thin film on the wafer 1 is greater than the predetermined thickness, the wafer 1 will be reloaded in the CMP apparatus 30 to perform another CMP process. If the thickness of the target thin film is less than the predetermined thickness, the wafer 1 will be delivered to a deposition apparatus (not shown) to perform a re-deposition process to correct the thickness of the target thin film. Therefore, the conventional method of controlling the target thin film thickness uses a feedback control mechanism to control the thickness of the target thin film.

The conventional method controls the thickness of the target thin film by modifying process parameters, re-performing a CMP process, or re-depositing a thin film according to a feedback data that cannot be obtained until the wafer is loaded out from the CMP apparatus. Thus, the conventional method takes more cycle time and cost.

### SUMMARY OF THE INVENTION

It is therefore one object of the claimed invention to provide a CMP apparatus for polishing a dielectric layer and a method of controlling dielectric layer thickness so reduce cycle time and cost.

According to the claimed invention, a CMP apparatus for polishing a dielectric layer is provided. The CMP apparatus includes a CMP unit for polishing a dielectric layer, a thickness monitoring unit for monitoring a thickness index of the dielectric layer after polished, and a thickness correcting unit for further reducing the dielectric layer by etching. The CMP unit, the thickness monitoring unit, and the thickness correcting unit are in-situ installed.

According to the claimed invention, a method of controlling dielectric layer thickness adapted for use in a CMP process is also provided. The method includes (a) using a CMP unit to polish a dielectric layer; (b) using a thickness monitoring unit to monitor the dielectric layer to obtain a thickness index; and (c) using a thickness correcting unit to further reduce the dielectric layer by etching in accordance with the thickness index. Steps (a), (b), and (c) are in-situ performed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart illustrating a conventional method of controlling a target thin film thickness in a CMP process.

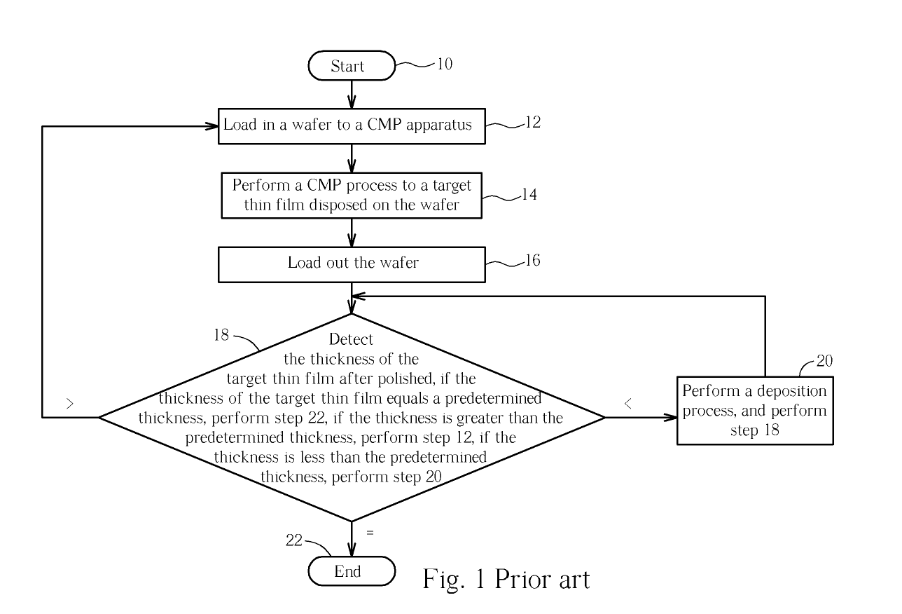

FIG. 2 is a diagram schematically illustrating a feedback control mechanism of a conventional method of controlling the target thin film thickness.

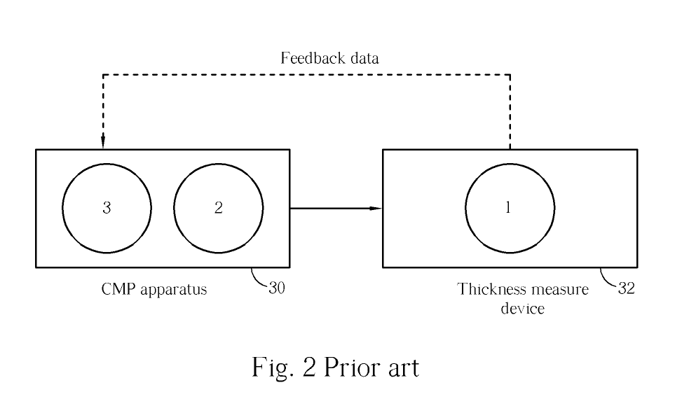

FIG. 3 is a flow chart illustrating a method of controlling a dielectric layer thickness adapted for use in a CMP process in accordance with a preferred embodiment of the present invention.

FIG. 4 is a function block diagram of a CMP apparatus for polishing a dielectric layer according to a preferred embodiment of the present invention.

FIG. 5 is a diagram schematically illustrating a feedforward control mechanism of a method of controlling a dielectric layer thickness in accordance with the present invention.

### DETAILED DESCRIPTION

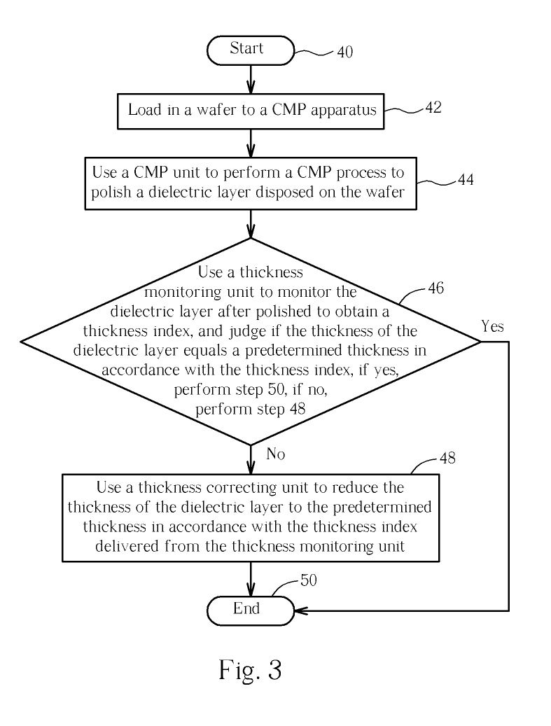

With reference to FIG. 3, FIG. 3 is a flow chart illustrating a method of controlling a dielectric layer thickness adapted for use in a CMP process in accordance with a preferred embodiment of the present invention. As shown in FIG. 3, the method includes the following steps:

Step 40: start;

Step 42: load in a wafer to a CMP apparatus;

Step 44: use a CMP unit to perform a CMP process to polish a dielectric layer disposed on the wafer;

Step 46: use a thickness monitoring unit to monitor the dielectric layer after polished to obtain a thickness index, and judge if the thickness of the dielectric layer equals a predetermined thickness in accordance with the thickness index, if yes, perform step 50, if no, perform step 48;

Step 48: use a thickness correcting unit to reduce the thickness of the dielectric layer to the predetermined thickness in accordance with the thickness index delivered from the thickness monitoring unit; and

Step 50: end.

In accordance with the method of controlling the dielectric layer thickness of the present invention, the thickness of the dielectric layer is first in-situ measured after the CMP process, and then the dielectric layer is further in-situ reduced to the predetermined thickness by a thickness correcting unit. For example, set the initial thickness of the dielectric layer is 20 Kilo angstroms, and the predetermined thickness of the dielectric layer is 10 kilo angstroms. Accordingly, a CMP process is performed to polish the dielectric layer, and a thickness monitoring unit is used to in-situ measure the thickness of the dielectric layer after polished. If the thickness of the dielectric layer after polished is 10.6 kilo angstroms, a thickness correcting unit is used to reduce the thickness of the dielectric layer to 10 kilo angstroms.

It is appreciated that the thickness correcting unit of the present invention reduces the thickness of the dielectric layer by chemical wet etching. Although the etching rate of chemical wet etching is slower than the polishing rate of CMP process, the chemical wet etching process is much more stable. Therefore, the chemical wet etching can accurately control the thickness of the dielectric layer to 10 kilo angstroms. Take the above embodiment for example, if the etching rate is 1 kilo angstroms per 60 seconds, it takes 36 seconds to reduce the thickness of the dielectric layer from 10.6 kilo angstroms to 10 kilo angstroms. In addition, the thickness monitoring unit and the thickness correcting unit can form a closed loop control to ensure the thickness of the dielectric layer. That is to say the thickness monitoring unit can monitor the thickness of the dielectric layer regularly and adjust the process time of the chemical wet etching process in time in case process deviation occurs. For instance, when the chemical wet etching has performed for 15 seconds, the chemical wet etching is halted and the thickness of the dielectric layer is measured again. If the thickness of the dielectric layer is 10.35 kilo angstroms as desired, the etching rate is proved stable and the chemical wet etching process is continued for 21 seconds. However, if the thickness of the dielectric layer is not 10.35 kilo angstroms, an exact etching rate can be calculated, and process time can be adjusted or other process parameters can be modified to make sure the thickness of the dielectric layer reach 10 kilo angstroms.

Since the polishing rate of CMP process is not stable, over-polishing may take place. To avoid the over-polishing problem, the target thickness of the dielectric layer after the CMP process may be set slightly larger than the predetermined thickness. For instance, the target thickness of the dielectric layer after polished can be set 11 kilo angstroms, while the predetermined thickness is set 10 kilo angstroms. Consequently, over-polishing will not occur in the CMP process.

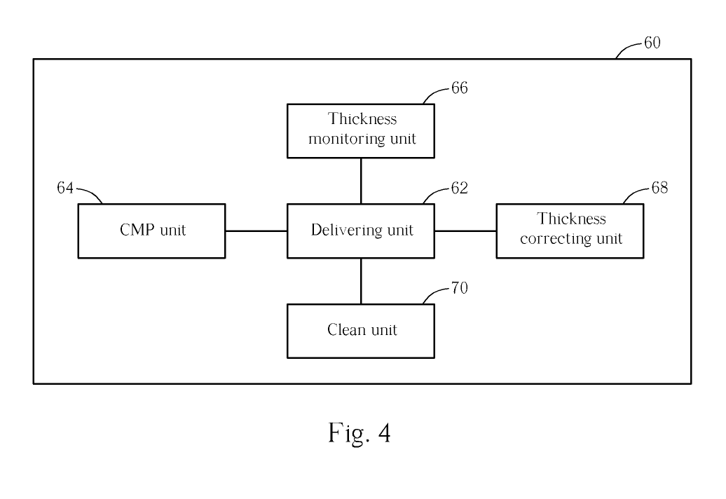

With reference to FIG. 4, FIG. 4 is a function block diagram of a CMP apparatus for polishing a dielectric layer according to a preferred embodiment of the present invention. As shown in FIG. 4, the CMP apparatus 60 includes a wafer delivering unit 62, a CMP unit 64, a thickness monitoring unit 66, and a thickness correcting unit 68. The CMP apparatus 60 is mainly used to polish a dielectric layer such as a silicon oxide layer, a silicon nitride layer, a silicon oxynitride layer, or a polycrystalline silicon layer. The wafer delivering unit 62 is used to load in/load out wafers and deliver wafers in the CMP apparatus 60. The CMP unit 64 is used to perform a CMP process, and can be single wafer type or multi wafer type. The thickness monitoring unit 66 can be any thickness measure device, such as an optical type thickness measure device or a contact type thickness measure device, in-situ arranged in the CMP apparatus 60. As different type of thickness measure device is used, the thickness monitoring unit 66 can detect a thickness index e.g. reflectivity or resistance of the dielectric layer, and obtain the thickness of the dielectric layer after proper calculations. This thickness data is delivered to the thickness correcting unit 68 as a reference to correct the thickness of the dielectric layer. The thickness correcting unit 68 can be a chemical wet etching device in-situ installed in the CMP apparatus 60, and etches the dielectric layer to the predetermined thickness according to the thickness data delivered from the thickness monitoring unit 66. In addition, the etching solution of the thickness correcting unit 68 can be hydrofluoric acid, phosphoric acid, nitric acid, or other solution as different dielectric layer is to be etched.

The CMP apparatus 60 may further include a clean unit 70 to perform a post CMP cleaning process to remove particles generated in the CMP process. It is noted that the thickness correcting unit 68 and the clean unit 70 can be individual set in the CMP apparatus 60, or the thickness correcting unit 68 and the clean unit 70 can be integrated together wherever necessary.

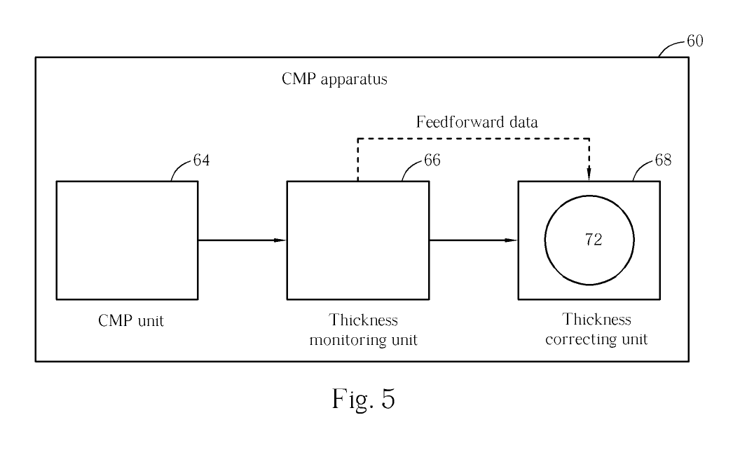

The method of controlling the dielectric layer thickness in-situ disposes the thickness monitoring unit 66 and the thickness correcting unit 68 in the CMP apparatus 60. Accordingly, as long as the thickness monitoring unit 66 detects the difference between the actual thickness and the predetermined thickness, this difference data will be transferred to the thickness correcting unit 68 so as to correct the thickness of the dielectric layer in time. Thus, the method of the present invention adopts a feedforward control mechanism. Referring to FIG. 5, FIG. 5 is a diagram schematically illustrating a feedforward control mechanism of a method of controlling a dielectric layer thickness in accordance with the present invention. As shown in FIG. 5, when a wafer 72 is loaded in the CMP apparatus 60, the CMP unit 64 first performs a CMP process to the wafer 72. Then, the wafer 72 is delivered to the thickness monitoring unit 66 and detected to obtain a thickness index. A difference data that represents the difference between the actual thickness and the predetermined thickness will be transferred to the thickness correcting unit 68 as a reference, and the thickness correcting unit 68 will correct the thickness of the dielectric layer disposed on the wafer 72 by chemical wet etching. Therefore, it can be seen that the method of the present invention adopts a feedforward control mechanism. In addition, every wafer 72 is monitored, and the dielectric layer of each wafer 72 may be etched to a different extent. Thus, the cycle time and cost are dramatically reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A chemical mechanical polishing (CMP) apparatus for polishing a dielectric layer, comprising:
a CMP unit for polishing a dielectric layer;
a thickness monitoring unit for monitoring a thickness index of the dielectric layer after polished; and
a thickness correcting unit for further reducing the dielectric layer by etching;
wherein the CMP unit, the thickness monitoring unit, and the thickness correcting unit are in-situ installed.

2. The CMP apparatus of claim 1, wherein the dielectric layer comprises a silicon oxide layer, a silicon nitride layer, a silicon oxynitride layer, or a polycrystalline silicon layer.

3. The CMP apparatus of claim 1, wherein the thickness monitoring unit is an optical type thickness measure device.

4. The CMP apparatus of claim 1, wherein the thickness monitoring unit is a contact type thickness measure device.

5. The CMP apparatus of claim 1, wherein the thickness correcting unit performs a chemical wet etching process to reduce the dielectric layer.

6. The CMP apparatus of claim 5, wherein the chemical wet etching process uses an etching solution comprising hydrofluoric acid, phosphoric acid, or nitric acid.

7. The CMP apparatus of claim 1, further comprising a clean unit.

8. A method of controlling a dielectric layer thickness adapted for use in a CMP process, the method comprising:
(a) using a CMP unit to polish a dielectric layer;
(b) using a thickness monitoring unit to monitor the dielectric layer to obtain a thickness index; and
(c) using a thickness correcting unit to reduce the dielectric layer by etching in accordance with the thickness index;
wherein steps (a), (b), and (c) are in-situ performed.

9. The method of claim 8, wherein the dielectric layer comprises a silicon oxide layer, a silicon nitride layer, a silicon oxynitride layer, or a polycrystalline silicon layer.

10. The method of claim 8, wherein the thickness index is obtained by an optical technique.

11. The method of claim 8, wherein the thickness index is obtained by a contact technique.

12. The method of claim 8, wherein step (c) comprises performing a chemical wet etching process.

13. The method of claim 12, wherein the chemical wet etching process uses an etching solution comprising hydrofluoric acid, phosphoric acid, or nitric acid.

14. The method of claim 8, further comprising performing a clean process subsequent to step (c).
